(19) United States
(12) Patent Application Publication
(10) Pub. No.: US 2014/0191350 A1
(43) Pub. Date: Jul. 10, 2014

(54) IMAGE SENSOR CHIP PACKAGE AND FABRICATING METHOD THEREOF

(71) Applicant: XINTEC INC., Zhongli City (TW)

(72) Inventors: Chih-Hao CHEN, Zhongli City (TW); Bai-Yao LOU, Taipei City (TW); Shih-Kuang CHEN, Kaohsiung City (TW)

(73) Assignee: XINTEC INC., Zhongli City (TW)

(21) Appl. No.: 14/150,637

(22) Filed: Jan. 8, 2014

Related U.S. Application Data
(60) Provisional application No. 61/750,983, filed on Jan. 10, 2013.

(51) Int. Cl. H01L 31/0232; H01L 27/146

(52) U.S. Cl. CPC H01L 31/0232; H01L 27/14618
USPC 257/432; 438/67

(57) ABSTRACT

An image sensor chip package is disclosed, which includes a substrate, an image sensor component formed on the substrate, a spacer formed on the substrate and surrounding the image sensor component, and a transparent plate. A stress notch is formed on a side of the transparent plate, and a breaking surface is extended from the stress notch. A method for fabricating the image sensor chip package is also disclosed.

### RELATED APPLICATIONS

This application claims priority to US provisional Application Ser. No. 61/750,983, filed Jan. 10, 2013, which is herein incorporated by reference.

### BACKGROUND

1. Field of Invention

The present invention relates to a chip package. More particularly, the present invention relates to an image sensor chip package.

2. Description of Related Art

An image sensor chip package mainly includes an image sensor chip and a transparent substrate disposed thereon. The transparent substrate may support the image sensor chip package during the fabrication.

However, the transparent substrate is generally made of glass, which has high rigidity, therefore, it takes lots of time on cutting the glass substrate thereby reducing the yield. Furthermore, the blade for cutting the glass substrate need to be changed frequently due to the high rigidity of the glass substrate, that may cause extra cost of changing the blades.

Therefore, there is a need for fabricating the image sensor chip package efficiently.

### SUMMARY

An aspect of the invention provides an image sensor chip package, which includes a substrate, an image sensor component formed on the substrate, a spacer formed on the substrate and surrounding the image sensor component, and a transparent plate disposed on the spacer. The transparent plate includes a stress notch and a breaking surface extended from the stress notch.

In one or more embodiments, the stress notch is a V-shaped notch, the breaking surface is extended from a vertical of the V-shape notch, and a surface roughness of the stress notch is different from a surface roughness of the breaking surface.

In one or more embodiments, the image sensor chip packager chip package further includes an optical component formed on the image sensor component.

In one or more embodiments, the transparent plate has an inner surface facing the substrate and an outer surface opposite to the inner surface, and the stress notch is formed on the inner surface.

In one or more embodiments, the image sensor chip package further includes a tape adhered on the outer surface of the transparent plate.

In one or more embodiments, a side surface of the substrate and the spacer adjacent the stress notch is a vertical surface.

In one or more embodiments, the image sensor chip package further includes a contact area formed on the substrate and connecting to the image sensor component, a via passing through the substrate, a conductive layer formed on a sidewall of the via and an outer surface of the substrate and being connected to the contact area, and a pad disposed on a part of the conductive layer located at the outer surface of the substrate, such that the image sensor component is electrically connected to the pad by the contact area and the conductive layer.

In one or more embodiments, the image sensor chip package further includes a passive layer formed on the outer surface of the substrate, and the passive layer has an opening for exposing the part of the conductive layer and the pad.

In one or more embodiments, a side surface of the substrate and the spacer adjacent the stress notch is an inclined surface, and the spacer comprises a recess for connecting the inclined surface to the stress notch.

In one or more embodiments, the image sensor chip package further includes a contact area formed on the substrate and connecting to the image sensor component, a conductive layer and a pad. The conductive layer is formed on the recess, the inclined surface, and an outer surface of the substrate, and the conductive layer is connected to the contact area. The pad is disposed on a part of the conductive layer located at the outer surface of the substrate, such that the image sensor component is electrically connected to the pad by the contact area and the conductive layer.

In one or more embodiments, the image sensor chip package further includes a passive layer formed on the outer surface of the substrate, the passive layer has an opening for exposing the part of the conductive layer and the pad.

In one or more embodiments, the transparent plate has an inner surface facing the substrate and an outer surface opposite to the inner surface, and the stress notch is formed on the outer surface.

In one or more embodiments, the substrate includes an extended section extended over the spacer, the image sensor chip package further includes a contact area disposed on the extended section, the contact are being connected to the image sensor component.

In one or more embodiments, the image sensor component and the contact area are disposed at opposite sides of the spacer.

In one or more embodiments, the image sensor chip package further includes a tape adhered on the outer surface of the substrate.

Another aspect of the invention provides a method for fabricating an image sensor chip package, the method includes providing a wafer, cutting a substrate of the wafer, forming a plurality of stress notches on a surface of a transparent plate of the wafer, and pressing the transparent plate, in which the transparent plate is broken along the stress notches, and the wafer is divided into a plurality of image sensor chip packages.

In one or more embodiments, the step of providing the wafer includes providing the substrate, forming a plurality of image sensor components on the substrate, forming a plurality of spacers on the substrate for separating the image sensor components, and disposing the transparent plate on the spacers, in which a plurality of chambers are formed between the transparent plate and the substrate, and the image sensors are disposed in the chambers respectively.

In one or more embodiments, the step of cutting the substrate of the wafer includes cutting into the spacers and the transparent plate for forming the stress notches on the surface of the transparent plate.

In one or more embodiments, the method further includes forming a plurality of contact areas on the substrate, the contact areas connecting to the image sensor components, forming a plurality of vias passing through the substrate, the vias are arranged corresponding to the contact areas, forming a conductive layer on a sidewall of the vias and an outer surface of the substrate, and forming a plurality of pads on the conductive layer.

In one or more embodiments, the step of cutting the substrate includes forming a plurality of trapezoid recesses on the substrate and the spacers.

In one or more embodiments, the method further includes forming a plurality of contact areas on the substrate, the contact areas connecting to the image sensor components, forming a conductive layer on the surface of the trapezoid recesses and an outer surface of the substrate, the conductive layer connecting to the contact areas, and forming a plurality of pads on the conductive layer.

In one or more embodiments, the stress notches are formed in the trapezoid recesses respectively, and a part of the conductive layer is filled in the stress notches.

In one or more embodiments, the step of providing the substrate includes providing the substrate, forming a plurality of image sensor components and a plurality of contact areas on the substrate, the contact areas connecting to the image sensor components, forming a plurality of spacers on the substrate for separating the image senor components, and disposing the transparent plate on the spacers, in which a plurality of chambers are formed between the transparent plate and the substrate, a part of the chambers are placed with the image sensor components, another part of the placed with the contact areas.

In one or more embodiments, the stress notches formed on the transparent plate are arranged corresponding to the contact areas.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A to FIG. 1E are cross-sectional schematic views of different states of an embodiment of a method for fabricating the image sensor chip package of the invention;

FIG. 2 is a partial view of the image sensor chip package 200 as shown in FIG. 1E;

FIG. 3A to FIG. 3G are cross-sectional schematic views of different states of another embodiment of a method for fabricating the image sensor chip package of the invention;

FIG. 4 is a partial view of the image sensor chip package 400 as shown in FIG. 3G;

FIG. 5A to FIG. 5D are cross-sectional schematic views of different states of yet another embodiment of a method for fabricating the image sensor chip package of the invention; and

FIG. 6 is a partial view of the image sensor chip package 600 as shown in FIG. 5D.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

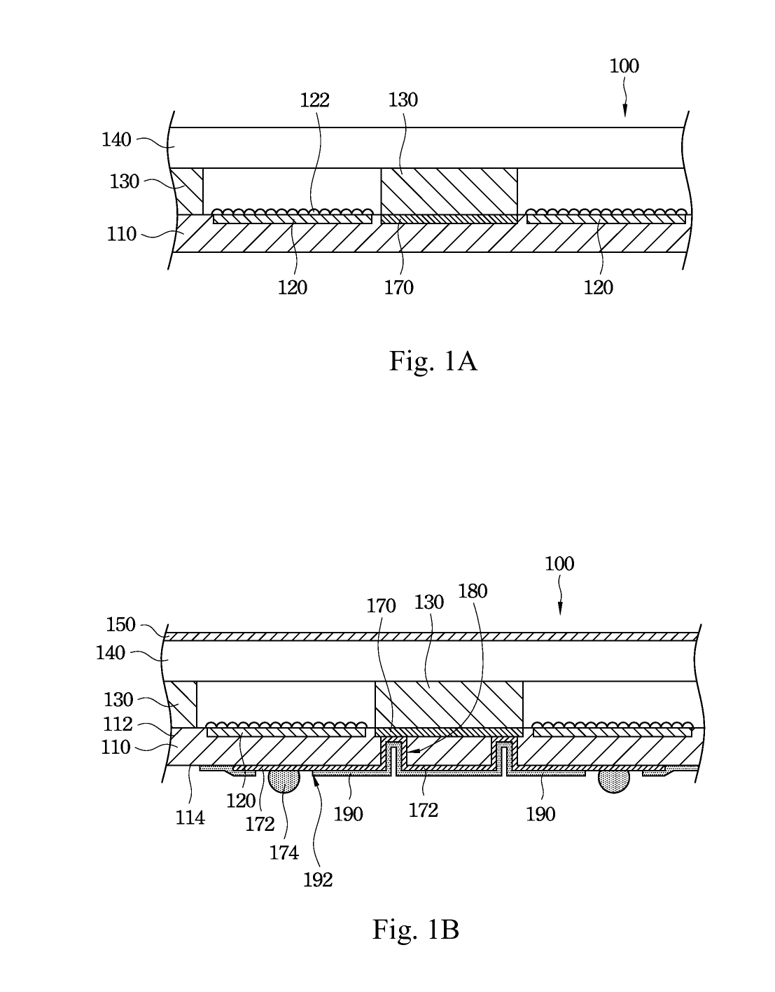

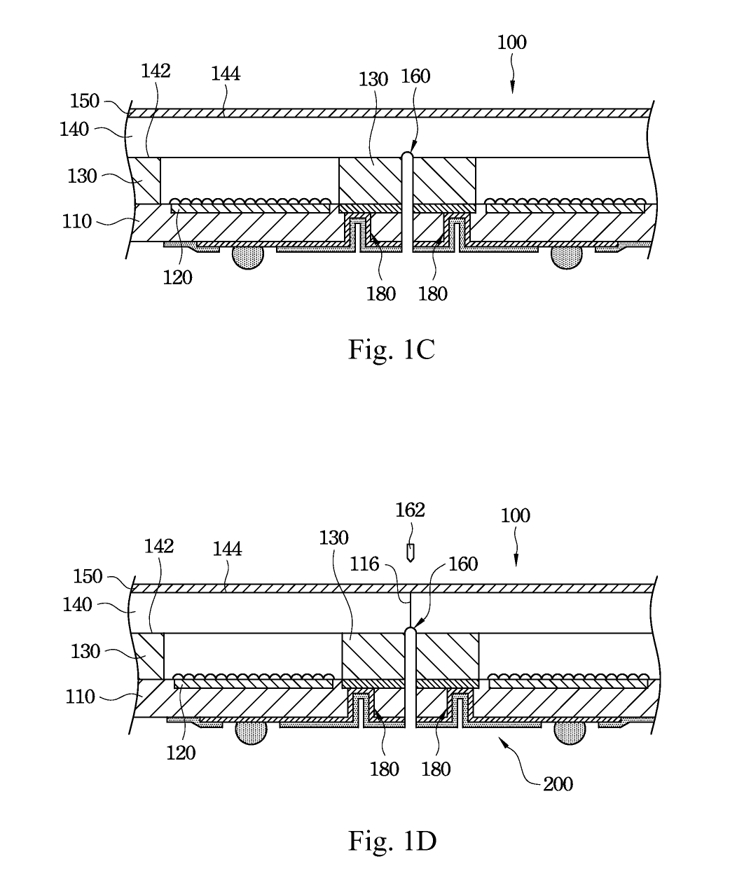

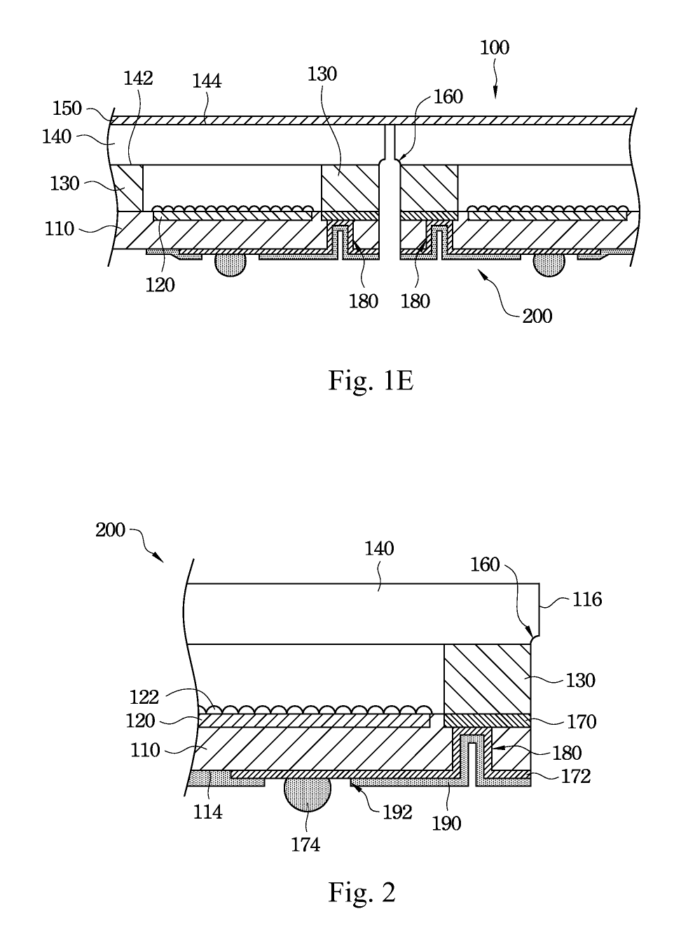

FIG. 1A to FIG. 1E are cross-sectional schematic views of different states of an embodiment of a method for fabricating the image sensor chip package of the invention.

In FIG. 1A, a wafer 100 is provided. The wafer 100 includes a substrate 110, a plurality of image sensor components 120 and a plurality of contact areas 170 formed on the substrate 110, a plurality of spacers 130, and a transparent plate 140. The substrate 110 can be a semiconductor substrate, such as a silicon substrate. The image sensor components 120 and the contact areas 170 can be formed on the substrate 110 by photolithography processes. The contact areas 170 are made of conductive material. The contact areas 170 are connected to the image sensor components 120 via inter-connection. A plurality of chambers are formed between the substrate 110 and the transparent plate 140, and the image sensors 120 are formed in the chambers. The spacers 130 are disposed on the substrate 110. The spacers 130 may surround the image sensor components 120 for separating the image sensor components 120. The spacers 130 can be formed above the contact areas 170. The spacers 130 can be utilized for connecting substrate 110 to the transparent plate 140. The substrate 110 includes at least silicon substrate, and the spaces 130 can be organic material, such as photo resists. The transparent plate 140 can be a glass plate for providing sufficient support and protection allowing light passing through. There are plural chambers formed between the substrate 110 and the transparent plate 140, and the image sensor components 120 are formed in the chambers. The wafer 100 may optionally include a plurality of optical components 122 formed on the image sensor components 120. The optical components 122 are formed on the surface of the image sensor components 120 for improving the image quality. The optical component 122 can be a micro lens array.

In FIG. 1B, a plurality of vias 180 are formed in the substrate 110. The vias 180 are formed corresponding the spacers 130, and the vias 180 are arranged under the spacers 130 in the drawing. The vias 122 pass through the substrate 110, such that an end of the vias 122 is led to the contact areas 170. The vias 122 may be formed by an etching process. There are two vias 122 formed under each spacer 130 in this embodiment.

FIG. 1B. also includes forming a conductive layer 172. The conductive layer 172 is formed in the vias 180 and on the substrate 110 by a physical vapor deposition process or a chemical vapor deposition process. The conductive layer 172 is formed at the sidewall of the vias 122 and the outer surface 114 of the substrate 110. The conductive layer 172 is further connected to the contact areas 170.

FIG. 1B further includes forming a passive layer 190. The passive layer 190 is formed on the outer surface 114 of the substrate 110. The passive layer 190 can be a solder mask. The passive layer 190 includes an opening 192 for exposing a part of the conductive layer 172. The passive layer 190 may be utilized for defining the places for conducting and protecting the conductive layer 172.

FIG. 1B further includes forming a plurality of pads 174. The pads 174 are formed on the outer surface 114 of the substrate 110 and are formed on the part of the conductive layer 172 exposed of the opening 192. The pads 174 can be solder balls or other possible types. The image sensor components 120 can be connected to the pads 174 by the contact area 170 and the conductive layer 172. The pads 174 may further electrically connect to the external circuit thus the image sensor components 120 can be electrically connected to the external circuit.

In FIG. 1C, the substrate 110 of the wafer 100 is cut. The step of cutting the substrate 110 can be performed by blade cutting or laser cutting. The substrate 110 has the inner surface 112 facing the transparent plate 140 and the outer surface 114 opposite to the inner surface 112. The substrate 110 is cut from the outer surface 114 toward the inner surface 112. The substrate 110 is cut corresponding to the spacers 130. More particularly, the substrate 110 and the spacer 130 are cut along the place between the vias 180. The wafer 100 further includes a tape 150 adhered on the transparent plate 150. The tape 150 can be a UV tape. The transparent plate 140 includes the inner surface 142 facing the substrate 110 and the outer surface 144 opposite to the inner surface 142. The step of cutting the substrate 110 and the spacer 130 can be continued, and the inner surface 142 of the transparent plate 140 is cut in order to form a plurality of stress notches 160 at the inner surface 142 of the transparent plate 140. The stress notches 160 can be V-shaped notches.

In FIG. 1D, the transparent plate 140 is pressed, especially pressing at the place corresponding to the stress notches 160. In some embodiments, the external force is applied on the tape 150 corresponding to the stress notches 160. A pressing tool 162, such as a presser or a needle, can be utilized for pressing the tape 150 at the places corresponding to the stress notches 160, and the pressure thereof is transferred to the transparent plate 140, such that the transparent plate 140 is broken at the stress notches 160 along a lattice orientation of the transparent plate 140.

The transparent plate 140 is not cut by the blade cutting process or by the laser cutting process in this embodiment. A smooth and regular breaking surface 116 is formed at the broken position because of the lattice orientation. The breaking surface 116 is extended from a vertical of the V-shaped stress notch 160. The surface roughness of the stress notch 160 is different from the roughness of the breaking surface 116. The wafer 100 is divided into a plurality of image sensor chip package 200 in this state.

In FIG. 1E, the image sensor chip packages 200 are taken from the tape 150 thereby getting the individual image sensor chip packages 200. The tape 150 itself is extendable, so that the tape 150 can be elongated in order to enlarge the spaces between the image sensor chip package 200, and the image sensor chip packages 200 can be taken from the tape 150 easily.

FIG. 2 is a partial view of the image sensor chip package 200 as shown in FIG. 1E. The image sensor chip package 200 includes the substrate 110, the image sensor component 120 formed on the substrate 110, the spacer 130 disposed on the substrate 110 and surrounding the image sensor component 120, and the transparent plate 140 disposed on the spacer 130. The transparent plate 140 has the stress notch 160 and the breaking surface 116 extended from the stress notch 160. In this embodiment, the side surface of the substrate 110 and the spacer 130 adjacent the stress notch 160 is a vertical surface.

The image sensor component 120 is formed on the substrate 110 and is arranged in the chamber between the substrate 110 and the transparent plate 140. The contact area 170 is formed on the substrate 110 and is disposed under the spacer 130. The contact area 170 is electrically connected to the image sensor component 120. The via 180 passes through the substrate 110, and an end of the via 180 is led to the contact area 170. The conductive layer 172 is formed on the sidewall of the via 180 and the outer surface 114 of the substrate 110. The conductive layer 172 is connected to the contact area 170. The image sensor chip package 200 includes the passive layer 190 disposed on the outer surface 114 of the substrate 110. The passive layer 190 can be a solder mask coated on the substrate 110. The passive layer 190 has the opening 192 for exposing the part of the conductive layer 172. The passive layer 190 may define the places for conducting and protect the conductive layer 172. The image sensor chip package 200 includes the pad 174. The pad 174 is disposed at the outer surface 114 of the substrate 110. The pad 174 can be a solder ball. The image sensor components 120 can be connected to the pad 174 by the contact area 170 and the conductive layer 172. The pad 174 is electrically connect to the external circuit thus the image sensor component 120 can be electrically connected to the external circuit.

The image sensor chip package 200 includes the optical components 122 formed on the image sensor component 120. The optical component 122 is formed on the surface of the image sensor component 120 for improving the image quality. The optical component 122 can be a micro lens array.

The stress notch 160 is formed by a cutting process, and the breaking surface 116 is formed by a cracking process. Therefore, the surface roughness of the stress notch 160 is different from the surface roughness of the breaking surface 116. Also, the transparent plate 140 is divided by the cracking process, compared with the convention blade cutting process, the cracking process may reduce time thereby raising yield and reduce the cost of changing the blade.

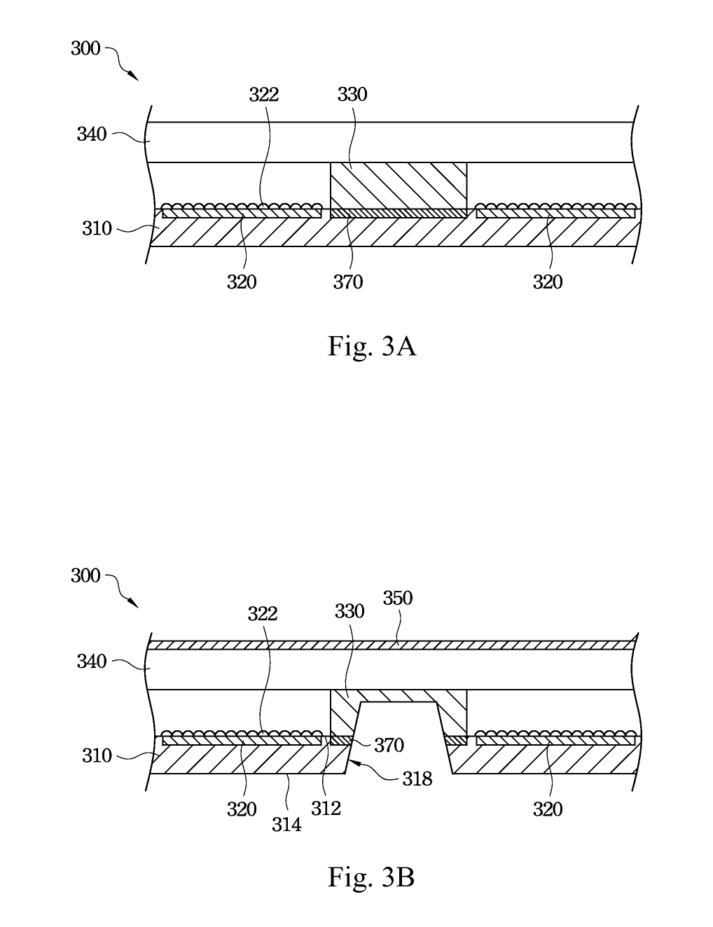

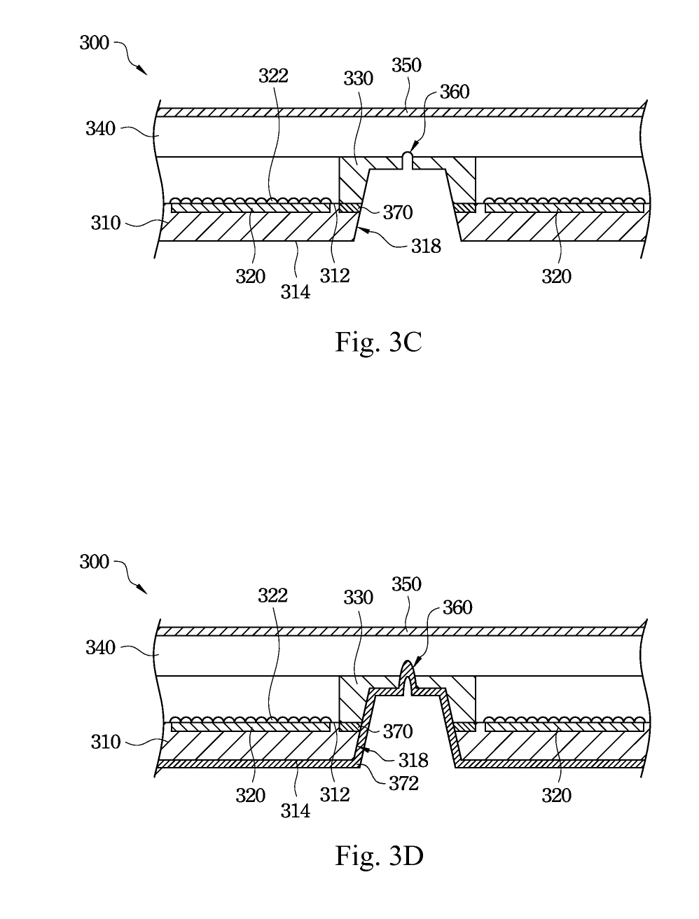

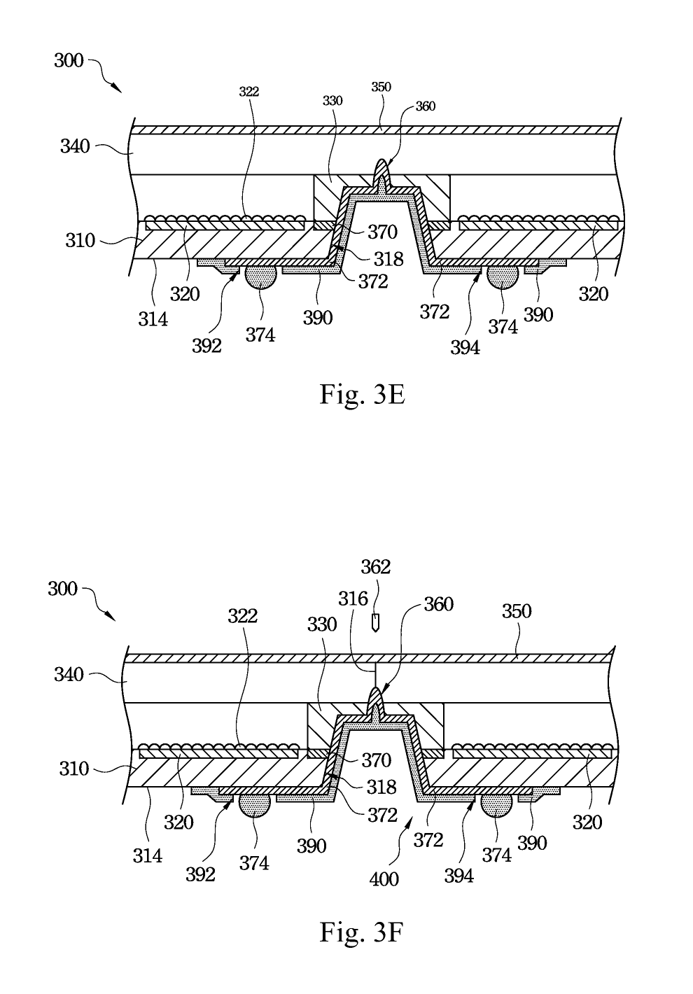

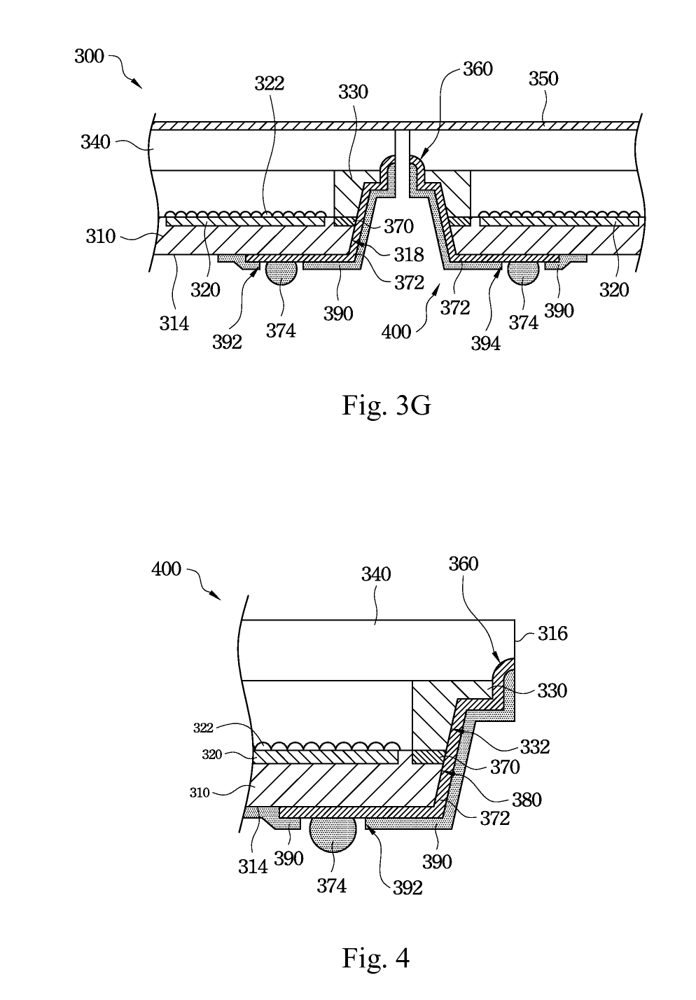

FIG. 3A to FIG. 3G are cross-sectional schematic views of different states of another embodiment of a method for fabricating the image sensor chip package of the invention.

In FIG. 3A, a wafer 300 is provided. The wafer 300 includes a substrate 310, a plurality of image sensor components 320 and a plurality of contact areas 370 formed on the substrate 310, a plurality of spacers 330, and a transparent plate 340. The substrate 310 can be a semiconductor substrate, such as a silicon substrate. The image sensor components 320 and the contact areas 370 can be formed on the substrate 310 by photolithography processes. The contact areas 370 are made of conductive material. The contact areas 370 are connected to the image sensor components 320 via inter-connection. The spacers 330 are disposed on the substrate 310. The spacers 330 may surround the image sensor components 320 for separating the image sensor components 320. The spacers 330 can be utilized for connecting substrate 310 to the transparent plate 340. The substrate 310 includes at least silicon substrate, and the spaces 330 can be organic material, such as photo resists. The transparent plate 340 can be a glass plate for providing sufficient support and protection allowing light passing through. There are plural chambers formed between the substrate 310 and the transparent plate 340, and the image sensor components 320 are formed in the chambers. The wafer 300 may optionally include a plurality of optical components 322 formed on the image sensor components 320. The optical components 322 are formed on the surface of the image sensor components 320 for improving the image quality. The optical component 322 can be a micro lens array.

In FIG. 3B, the substrate 310 of the wafer 300 is cut. The step of cutting the substrate 110 can be performed by tool cutting or etching. The substrate 310 has the inner surface 312 facing the transparent plate 340 and the outer surface 314 opposite to the inner surface 312. The substrate 310 is cut from the outer surface 314 toward the inner surface 312. The substrate 310 is cut corresponding to the spacers 330. In this embodiment, the step of cutting the substrate 310 of the wafer 300 includes forming a plurality of trapezoid recesses 318 on the substrate 310 and the spacers 330. The trapezoid recess 318 has a narrower end and a wider end, and the narrower end is formed on the spacer 330. The wafer 300 may include a tape 350 adhered on the transparent plate 340, in which the tape 350 can be a UV tape. The contact area 370 is exposed at the surface of the trapezoid recess 318.

In FIG. 3C, a plurality of stress notches 360 are formed on the surface of the transparent plate 340. The transparent plate 340 includes the inner surface 342 facing the substrate 310 and the outer surface 344 opposite to the inner surface 342. The stress notches 360 are formed at the inner surface 342 of the transparent plate 340. The spacer 330 and the transparent plate 340 are cut by blade or laser in order to form the stress notch 360 at the inner surface 342 of the transparent plate 340. The stress notch 360 can be a V-shaped notch, and the stress notch is formed on the top of the trapezoid recess 318.

In FIG. 3D, a conductive layer 372 is formed on the outer surface 314 of the substrate 310 and the sidewall of the trapezoid recess 318. The conductive layer 372 is connected to the contact area 370. The connecting portion of the conductive layer 372 and the contact area 370 is similar to a T-shaped structure. The conductive layer 372 can be formed on the outer surface 314 of the substrate 310 and the sidewall of the trapezoid recess 318 by physical vapor deposition or chemical vapor deposition. A part of the conductive layer 372 is filled into the stress notch 360.

In FIG. 3E, a passive layer 390 is formed on the outer surface 314 of the substrate 310. The passive layer 390 can be a solder mask. The passive layer 390 may be utilized for defining the places for conducting and protecting the conductive layer 372. The passive layer 390 includes a plurality of openings 392 for exposing a part of the conductive layer 372. Also, a plurality of pads 374 are formed on the outer surface 314 of the substrate 310 and are formed on the part of the conductive layer 372 exposed of the opening 392. The image sensor components 320 can be connected to the pads 374 by the contact area 370 and the conductive layer 372. The pads 374 may further electrically connect to the external circuit thus the image sensor components 320 can be electrically connected to the external circuit. The pads 374 can be solder balls or other possible types.

In FIG. 3F, the transparent plate 340 is pressed, especially pressing at the place corresponding to the stress notches 360. In some embodiments, the external force is applied on the tape 350 corresponding to the stress notches 360. A pressing tool 362, such as a presser or a needle, can be utilized for pressing the tape 350 at the places corresponding to the stress notches 360, and the pressure thereof is transferred to the transparent plate 340, such that the transparent plate 340 is broken at the stress notches 360 along a lattice orientation of the transparent plate 340. A smooth and regular breaking surface 316 is formed at the broken position because of the lattice orientation. The breaking surface 316 is extended from a vertical of the V-shaped stress notch 360. The surface roughness of the stress notch 360 is different from the roughness of the breaking surface 316. The wafer 300 is divided into a plurality of image sensor chip package 400 in this state.

In FIG. 3G, the image sensor chip packages 400 are taken from the tape 350 thereby getting the individual image sensor chip packages 400. The tape 350 itself is extendable, so that the tape 350 can be elongated in order to enlarge the spaces between the image sensor chip package 400, and the image sensor chip packages 400 can be taken from the tape 350 easily.

FIG. 4 is a partial view of the image sensor chip package 400 as shown in FIG. 3G. The image sensor chip package 400 includes the substrate 310, the image sensor component 320 formed on the substrate 310, the spacer 330 disposed on the substrate 310 and surrounding the image sensor component 320, and the transparent plate 340 disposed on the spacer 330. The transparent plate 340 has the stress notch 360 and the breaking surface 316 extended from the stress notch 360. In this embodiment, the side surface of the substrate 310 and the spacer 330 adjacent the stress notch 360 is an inclined surface 380. The spacer 330 has a recess 332 thereon for connecting the inclined surface 380 and the stress notch 360.

The image sensor chip package 400 includes the conductive layer 372 and the pad 374. The image sensor component 320 is formed on the substrate 310 and is arranged in the chamber between the substrate 310 and the transparent plate 340. The contact area 370 is formed on the substrate 310 and is disposed under the spacer 330. The contact area 370 is electrically connected to the image sensor component 320.

The conductive layer 372 is formed on the outer surface 314 of the substrate 310, the inclined surface 380 and the recess 332 on the spacer 330. The conductive layer 372 can be formed on the outer surface 314 of the substrate 310, the inclined surface 380 and the recess 332 on the spacer 330 by physical vapor deposition or chemical vapor deposition. The conductive layer 372 is connected to the contact area 370.

The pad 374 is disposed at the outer surface 314 of the substrate 310. The pad 374 can be a solder ball. The image sensor components 320 can be connected to the pad 374 by the contact area 370 and the conductive layer 372. The pad 374 is electrically connect to the external circuit thus the image sensor component 320 can be electrically connected to the external circuit.

The image sensor chip package 400 includes the optical components 322 formed on the image sensor component 320. The optical component 322 is formed on the surface of the image sensor component 320 for improving the image quality. The optical component 322 can be a micro lens array.

The image sensor chip package 400 includes the passive layer 390 disposed on the outer surface 314 of the substrate 310. The passive layer 390 can be a solder mask coated on the substrate 310. The passive layer 390 has the opening 392 for exposing the part of the conductive layer 372. The passive layer 390 may prevent the pad 374 from touching each other and define the places for conducting and protect the conductive layer 372.

The stress notch 360 is formed by a cutting process, and the breaking surface 316 is formed by a cracking process. Therefore, the surface roughness of the stress notch 360 is different from the surface roughness of the breaking surface 316. Also, the transparent plate 340 is divided by the cracking process, compared with the convention blade cutting process, the cracking process may reduce time thereby raising yield and reduce the cost of changing the blade.

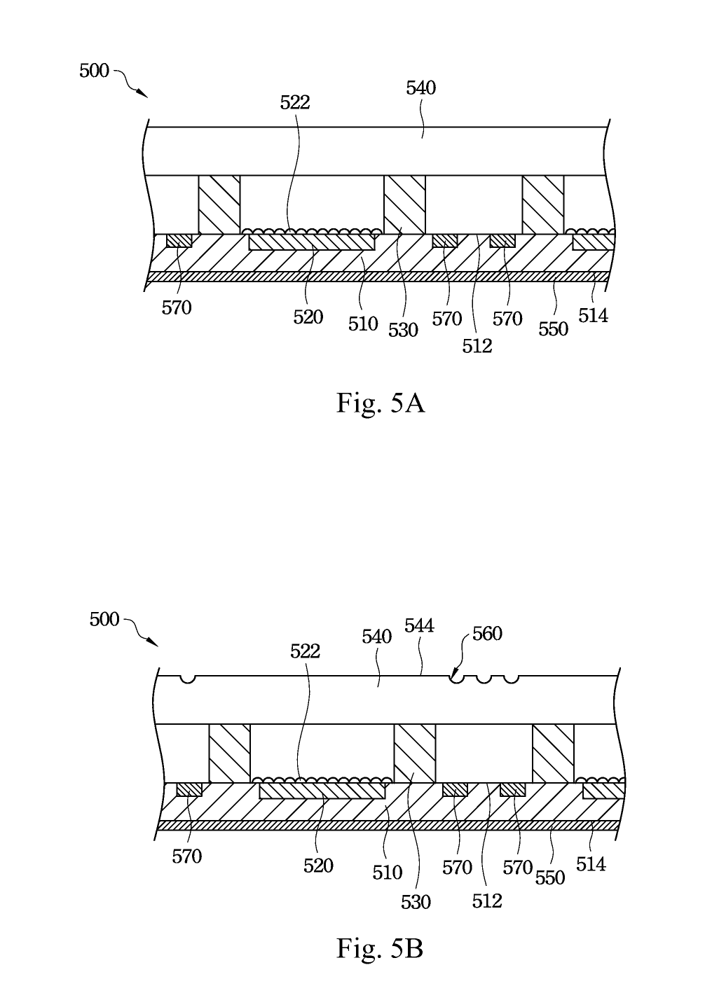

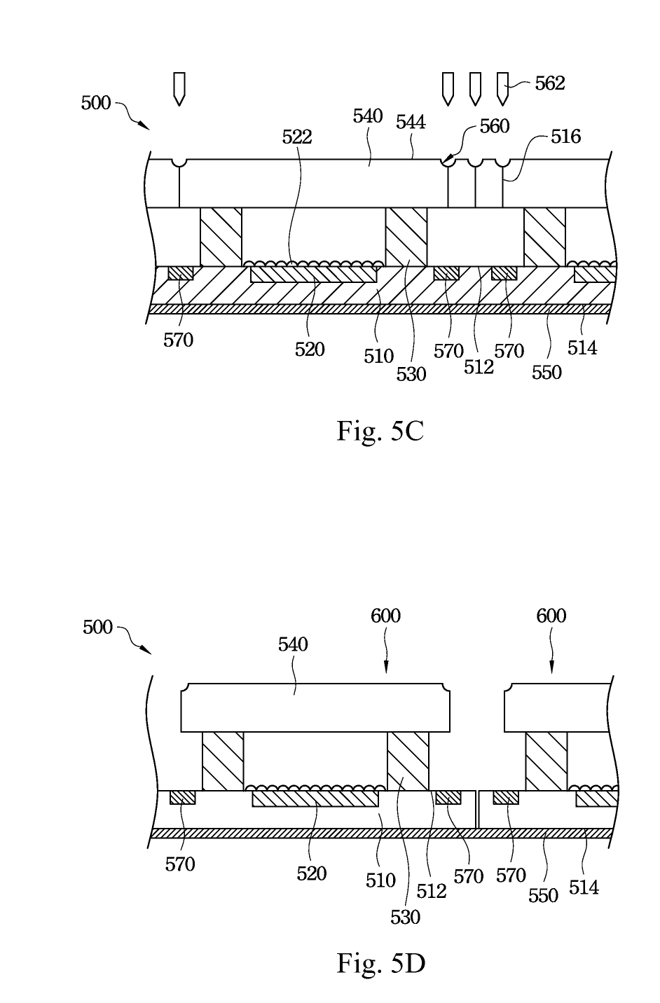

FIG. 5A to FIG. 5D are cross-sectional schematic views of different states of yet another embodiment of a method for fabricating the image sensor chip package of the invention.

In FIG. 5A, a wafer 500 is provided. The wafer 500 includes a substrate 510, a plurality of image sensor components 520 and a plurality of contact areas 570 formed on the substrate 510, a plurality of spacers 530, and a transparent plate 540. The substrate 510 can be a semiconductor substrate, such as a silicon substrate. The image sensor components 520 and the contact areas 570 can be formed on the substrate 510 by photolithography processes. The contact areas 570 are made of conductive material. The contact areas 570 are connected to the image sensor components 520 via inter-connection. The spacers 530 are disposed on the substrate 510. The spacers 530 may surround the image sensor components 520 for separating the image sensor components 520. The spacers 530 can be utilized for connecting substrate 510 to the transparent plate 540. The contact area 570 and the image sensor component 520 are disposed at opposite sides of the spacer 530.

The substrate 510 includes at least silicon substrate, and the spaces 530 can be organic material, such as photo resists. The transparent plate 540 can be a glass plate for providing sufficient support and protection allowing light passing through. The wafer 500 further includes a tape 550. The substrate 510 has the inner surface 512 facing the transparent plate 540 and the outer surface 514 opposite to the inner surface 512. The tape 550 is adhered on the outer surface 514.

There are plural chambers formed between the substrate 510 and the transparent plate 540. The image sensor components 520 are formed in a part of the chambers, and the contact area 570 are formed in another part of the chambers. Each of the contact areas 570 is electrically connected to the corresponding image sensor component 520 by an inter-connection.

The wafer 500 may optionally include a plurality of optical components 522 formed on the image sensor components 520. The optical components 522 are formed on the surface of the image sensor components 520 for improving the image quality. The optical component 522 can be a micro lens array.

In FIG. 5B, a plurality of stress notches 560 are formed on the surface of the transparent plate 540. The transparent plate 540 includes the inner surface 542 facing the substrate 510 and the outer surface 544 opposite to the inner surface 542. The stress notches 560 are formed at the outer surface 544 of the transparent plate 540. The transparent plate 540 are cut by blade or laser in order to form the stress notch 560 at the outer surface 544 of the transparent plate 540. The stress notch 560 can be a V-shaped notch. The position of the stress notch 560 is corresponding to the chamber where the contact area 570 is formed. The stress notch 560 is formed outside of the spacer 530. The stress notch 560 is not arranged on the spacer 530.

In FIG. 5C, the transparent plate 540 is pressed, especially pressing at the place corresponding to the stress notches 560. A pressing tool 562, such as a presser or a needle, can be utilized for pressing at the stress notches 560, such that the transparent plate 540 is broken at the stress notches 560 along a lattice orientation of the transparent plate 540. A smooth and regular breaking surface 516 is formed at the broken position because of the lattice orientation. The breaking surface 516 is extended from a vertical of the V-shaped stress notch 560. The surface roughness of the stress notch 560 is different from the roughness of the breaking surface 516. The broken part of the transparent plate 540 above the contact area 570 can be removed.

In FIG. 5D, the substrate 510 of the wafer 500 is cut. The step of cutting the substrate 510 can be performed by tool cutting or etching. The substrate 510 is cut from the inner surface 512 toward the outer surface 514. The substrate 510 is cut between the spacers 530. The wafer 500 is divided into a plurality of image sensor ship packages 600. Then the image sensor chip packages 600 are taken from the tape 550 thereby getting the individual image sensor chip packages 600.

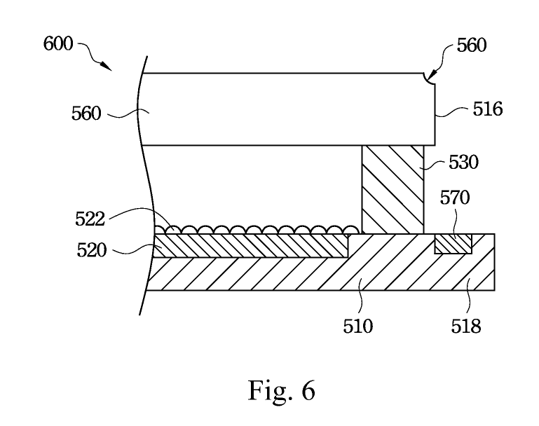

FIG. 6 is a partial view of the image sensor chip package 600 as shown in FIG. 5D. The image sensor chip package 600 includes the substrate 510, the image sensor component 520 formed on the substrate 510, the spacer 530 disposed on the substrate 510 and surrounding the image sensor component 520, the transparent plate 540 disposed on the spacer 530, and the contact area 570 formed on the substrate 510. The transparent plate 540 has the stress notch 560 and the breaking surface 516 extended from the stress notch 560.

The image sensor component 520 is formed on the substrate 510 and is disposed in the chamber between the transparent plate 540 and the substrate 510. The substrate 510 includes an extended section 518 extended over the spacer 530. The contact area 570 is formed on the extended section 518. The contact area 570 is electrically connected to the image sensor component 520. The contact area 570 and the image sensor component 520 are disposed at opposite sides of the spacer 530. The image sensor component 520 is electrically connected to the external circuit by the contact area 570.

The image sensor chip package 600 includes the optical components 522 formed on the image sensor component 520. The optical component 522 is formed on the surface of the image sensor component 520 for improving the image quality. The optical component 522 can be a micro lens array.

According to above embodiments, the stress notches are formed on the transparent plate, and the transparent plate is pressed, such that the transparent plate is cracked along the stress notch. The transparent plate can be a glass plate, thus the transparent plate is cracked along a lattice orientation of the transparent plate. Compared with the convention blade cutting process, the transparent plate is divided by the cracking process, which may reduce time thereby raising yield and reduce the cost of changing the blade.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An image sensor chip package, comprising:
a substrate;
an image sensor component formed on the substrate;
a spacer formed on the substrate and surrounding the image sensor component; and
a transparent plate disposed on the spacer, wherein the transparent plate comprises a stress notch and a breaking surface extended from the stress notch.

2. The image sensor chip package of claim 1, wherein the stress notch is a V-shaped notch, the breaking surface is extended from a vertical of the V-shape notch, and a surface roughness of the stress notch is different from a surface roughness of the breaking surface.

3. The image sensor chip package of claim 1, further comprising an optical component formed on the image sensor component.

4. The image sensor chip package of claim 1, wherein the transparent plate has an inner surface facing the substrate and an outer surface opposite to the inner surface, and the stress notch is formed on the inner surface.

5. The image sensor chip package of claim 4, further comprising a tape adhered on the outer surface of the transparent plate.

6. The image sensor chip package of claim 4, wherein a side surface of the substrate and the spacer adjacent the stress notch is a vertical surface.

7. The image sensor chip package of claim 4, further comprising:
a contact area formed on the substrate and connecting to the image sensor component;
a via passing through the substrate;
a conductive layer formed on a sidewall of the via and an outer surface of the substrate, the conductive layer being connected to the contact area; and
a pad disposed on a part of the conductive layer located at the outer surface of the substrate, such that the image sensor component is electrically connected to the pad by the contact area and the conductive layer.

8. The image sensor chip package of claim 7, further comprising a passive layer formed on the outer surface of the substrate, the passive layer having an opening for exposing the part of the conductive layer and the pad.

9. The image sensor chip package of claim 4, wherein a side surface of the substrate and the spacer adjacent the stress notch is an inclined surface, and the spacer comprises a recess for connecting the inclined surface to the stress notch.

10. The image sensor chip package of claim 9, further comprising:
a contact area formed on the substrate and connecting to the image sensor component;
a conductive layer formed on the recess, the inclined surface, and an outer surface of the substrate, the conductive layer being connected to the contact area; and
a pad disposed on a part of the conductive layer located at the outer surface of the substrate, such that the image sensor component is electrically connected to the pad by the contact area and the conductive layer.

11. The image sensor chip package of claim 10, further comprising a passive layer formed on the outer surface of the substrate, the passive layer having an opening for exposing the part of the conductive layer and the pad.

12. The image sensor chip package of claim 1, wherein the transparent plate has an inner surface facing the substrate and an outer surface opposite to the inner surface, and the stress notch is formed on the outer surface.

13. The image sensor chip package of claim 12, wherein the substrate comprises an extended section extended over the spacer, the image sensor chip package further comprises a contact area disposed on the extended section, the contact are being connected to the image sensor component.

14. The image sensor chip package of claim 13, wherein the image sensor component and the contact area are disposed at opposite sides of the spacer.

15. The image sensor chip package of claim 12, further comprising a tape adhered on the outer surface of the substrate.

16. A method for fabricating an image sensor chip package, comprising:
providing a wafer;
cutting a substrate of the wafer;
forming a plurality of stress notches on a surface of a transparent plate of the wafer; and
pressing the transparent plate, wherein the transparent plate is broken along the stress notches, and the wafer is divided into a plurality of image sensor chip packages.

17. The method for fabricating an image sensor chip package of claim 16, wherein the step of providing the wafer comprises:
providing the substrate;
forming a plurality of image sensor components on the substrate;
forming a plurality of spacers on the substrate for separating the image sensor components; and
disposing the transparent plate on the spacers, wherein a plurality of chambers are formed between the transparent plate and the substrate, and the image sensors are disposed in the chambers respectively.

18. The method for fabricating an image sensor chip package of claim 17, wherein the step of cutting the substrate of the wafer comprises cutting into the spacers and the transparent plate for forming the stress notches on the surface of the transparent plate.

19. The method for fabricating an image sensor chip package of claim 18, further comprising:
forming a plurality of contact areas on the substrate, the contact areas connecting to the image sensor components;
forming a plurality of vias passing through the substrate, the vias are arranged corresponding to the contact areas;
forming a conductive layer on a sidewall of the vias and an outer surface of the substrate; and
forming a plurality of pads on the conductive layer.

20. The method for fabricating an image sensor chip package of claim 17, wherein the step of cutting the substrate comprises forming a plurality of trapezoid recesses on the substrate and the spacers.

21. The method for fabricating an image sensor chip package of claim 20, further comprising:
forming a plurality of contact areas on the substrate, the contact areas connecting to the image sensor components;
forming a conductive layer on the surface of the trapezoid recesses and an outer surface of the substrate, the conductive layer connecting to the contact areas; and
forming a plurality of pads on the conductive layer.

22. The method for fabricating an image sensor chip package of claim 21, wherein the stress notches are formed in the trapezoid recesses respectively, and a part of the conductive layer is filled in the stress notches.

23. The method for fabricating an image sensor chip package of claim 16, wherein the step of providing the substrate comprises:
providing the substrate;
forming a plurality of image sensor components and a plurality of contact areas on the substrate, the contact areas connecting to the image sensor components;
forming a plurality of spacers on the substrate for separating the image senor components; and
disposing the transparent plate on the spacers, wherein a plurality of chambers are formed between the transparent plate and the substrate, a part of the chambers are placed with the image sensor components, another part of the placed with the contact areas.

24. The method for fabricating an image sensor chip package of claim 23, wherein the stress notches formed on the transparent plate are arranged corresponding to the contact areas.
